(19) United States
(12) Patent Application Publication
(10) Pub. No.: US 2012/0115259 A1
(43) Pub. Date: May 10, 2012

(54) METHOD FOR FABRICATING FLEXIBLE ELECTRONIC DEVICE AND ELECTRONIC DEVICE FABRICATED THEREBY

(76) Inventors: Keon Jae LEE, Daejeon (KR); Min Koo, Gyeonggi-do (KR); Geon Tae Hwang, Busan (KR)

(21) Appl. No.: 13/292,772

(22) Filed: Nov. 9, 2011

(30) Foreign Application Priority Data
Nov. 10, 2010 (KR) 10-2010-0111319
Jan. 6, 2011 (KR) 10-2011-0001280
Sep. 15, 2011 (KR) 10-2011-0092755

(51) Int. Cl. H01L 21/302; B05D 3/06; B05D 5/12; H01L 21/268; H01L 21/30

(52) U.S. Cl. 438/19; 438/795; 438/458; 427/554; 257/E21.347; 257/E21.214; 257/E21.211

(57) ABSTRACT

Disclosed are a method for fabricating a flexible electronic device using laser lift-off and an electronic device fabricated thereby. More particularly, disclosed are a method for fabricating a flexible electronic device using laser lift-off allowing for fabrication of a flexible electronic device in an economical and stable way by separating a device such as a secondary battery fabricated on a sacrificial substrate using laser, and an electronic device fabricated thereby.

### CROSS-REFERENCE TO RELATED APPLICATIONS

This application claims priority under 35 U.S.C. §119 to Korean Patent Application No. 10-2010-0111319 filed on Nov. 11, 2010, 10-2011-0001280 filed on Jan. 6, 2011, and 10-2011-0092755 filed on Sep. 15, 2011, in the Korean Intellectual Property Office, the disclosures of which are incorporated herein by reference in their entirety.

### TECHNICAL FIELD OF THE INVENTION

The present disclosure relates to a method for fabricating a flexible electronic device using laser lift-off and an electronic device fabricated thereby. More particularly, the disclosure relates to a method for fabricating a flexible electronic device using laser lift-off allowing for fabrication of a flexible electronic device in an economical and stable way by separating a device such as a secondary battery fabricated on a sacrificial substrate using laser, and an electronic device fabricated thereby.

### BACKGROUND OF THE INVENTION

With the development in information technology, a new type of high-performance flexible device is required. In order to operate such an electronic device, the flexible energy device technique of storing and supplying energy is required in addition to the high-performance semiconductor device. At present, it is impossible to realize high-performance energy storage with a plastic substrate since high-temperature processes are inapplicable. At present, electronic devices are fabricated on a hard silicon substrate because the devices are fabricated via high-performance semiconductor processes. However, the substrate is restricted in applications to piezoelectric devices, secondary batteries, or the like.

When fabricating such a flexible electronic device, the technique of separating the electronic device, e.g. a secondary battery, fabricated on the sacrificial substrate, e.g. silicon, glass or sapphire substrate, is very important.

### SUMMARY OF THE INVENTION

The present disclosure is directed to providing a method for fabricating a flexible electronic device allowing for easier separation of the electronic device from a sacrificial substrate, and a flexible electronic device fabricated thereby.

### BRIEF DESCRIPTION OF THE DRAWINGS

The above and other objects, features and advantages of the present disclosure will become apparent from the following description of certain exemplary embodiments given in conjunction with the accompanying drawings, in which:

FIGS. 1-14 show a process of fabricating a plastic secondary battery according to an exemplary embodiment of the present disclosure;

FIGS. 15-27 show a process of fabricating a plastic secondary battery according to another exemplary embodiment of the present disclosure; and

FIGS. 28-39 show a process of fabricating a plastic secondary battery according to another exemplary embodiment of the present disclosure.

### DETAILED DESCRIPTION OF INVENTION

The advantages, features and aspects of the present disclosure will become apparent from the following description of the embodiments with reference to the accompanying drawings, which is set forth hereinafter. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. The terminology used herein is for the purpose of describing particular embodiments only and is not intended to be limiting of the example embodiments. As used herein, the singular forms “a”, “an” and “the” are intended to include the plural forms as well, unless the context clearly indicates otherwise. It will be further understood that the terms “comprises” and/or “comprising”, when used in this specification, specify the presence of stated features, integers, steps, operations, elements, and/or components, but do not preclude the presence or addition of one or more other features, integers, steps, operations, elements, components, and/or groups thereof.

Hereinafter, exemplary embodiments will be described in detail with reference to the accompanying drawings.

In the present disclosure, a sacrificial substrate such as a glass substrate is used such that laser irradiated from the back surface of the substrate is transmitted to the front surface thereof to provide heat. As a consequence, hydrogen outgassing occurs at the front surface of the sacrificial substrate and an electronic device fabricated on the front surface of the sacrificial substrate is easily separated from the sacrificial substrate. Accordingly, the electronic device such as a secondary battery fabricated on the front surface of the substrate can be easily separated from the sacrificial substrate without requiring an additional wet etching process simply by irradiating laser to the back surface. Then, the separated electronic device is transferred to a flexible substrate to fabricate a flexible electronic device.

Hereinafter, the method for fabricating a flexible electronic device according to the present disclosure is described with a secondary battery as an example of the electronic device. However, the electronic device is not limited thereto and any type of electronic device that can be fabricated on a silicon or glass substrate may be fabricated by the method according to the present disclosure. In an exemplary embodiment of the present disclosure, the secondary battery is a solid-state battery.

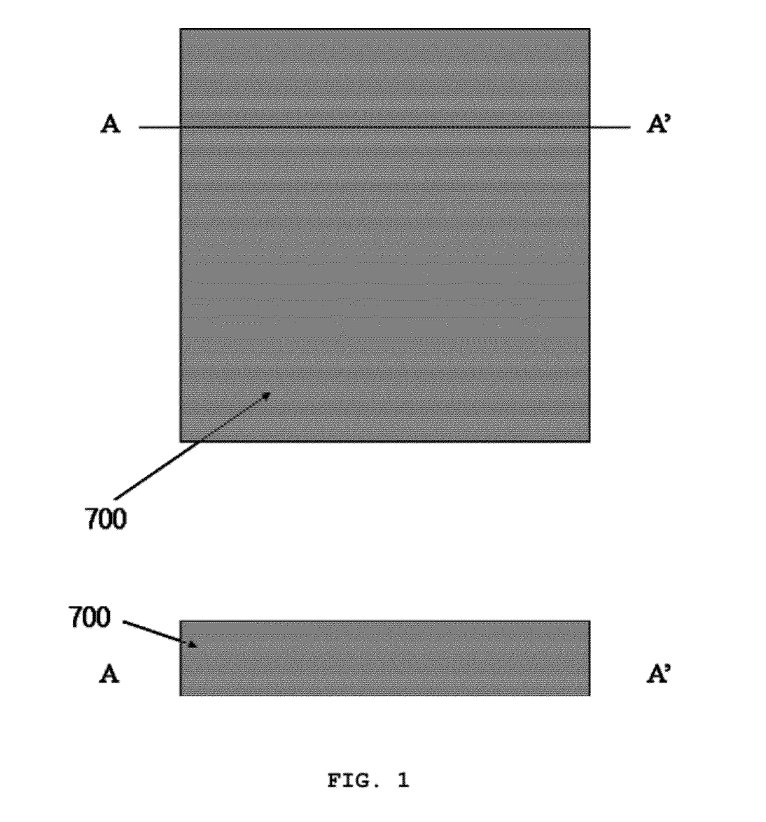

Referring to FIG. 1, a glass substrate 700 is provided as a sacrificial substrate. But, the glass substrate is only an example of the sacrificial substrate that can be used in the present disclosure and any substrate that allows transmission of laser from its back surface so that heat can be focused on its front surface may be used as the sacrificial substrate.

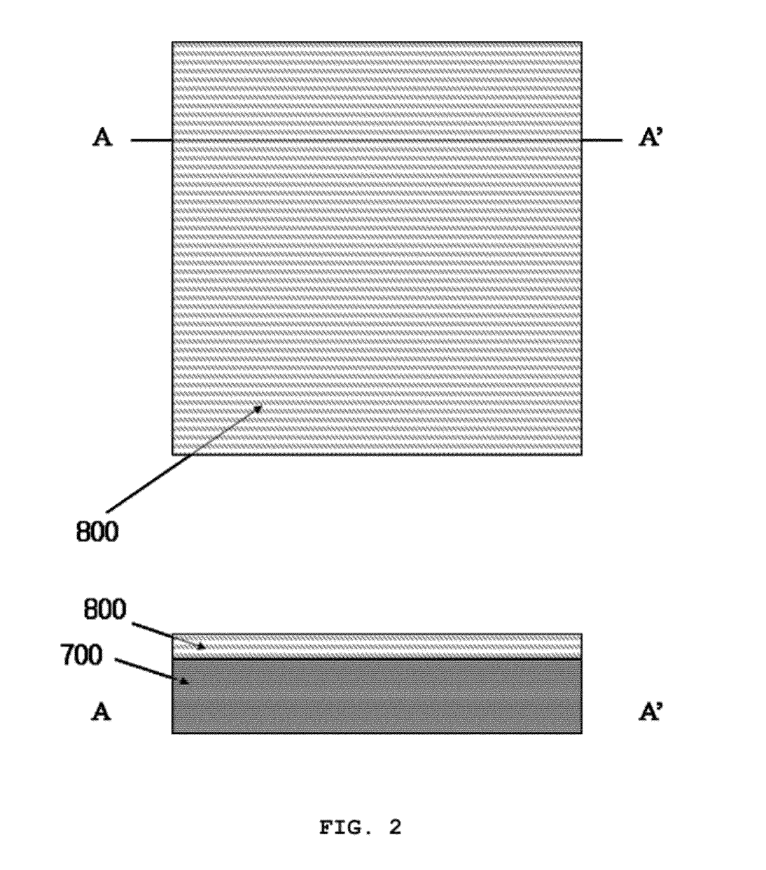

Referring to FIG. 2, a hydrogen-containing amorphous silicon (a-Si:H) layer 800 is deposited on a surface (front surface) of the glass substrate 700. The hydrogen-containing amorphous silicon layer 800 serves as a separation layer that outgases hydrogen contained therein by laser irradiated from the back surface of the substrate so that an electronic device formed thereon can be separated from the sacrificial substrate therebelow.

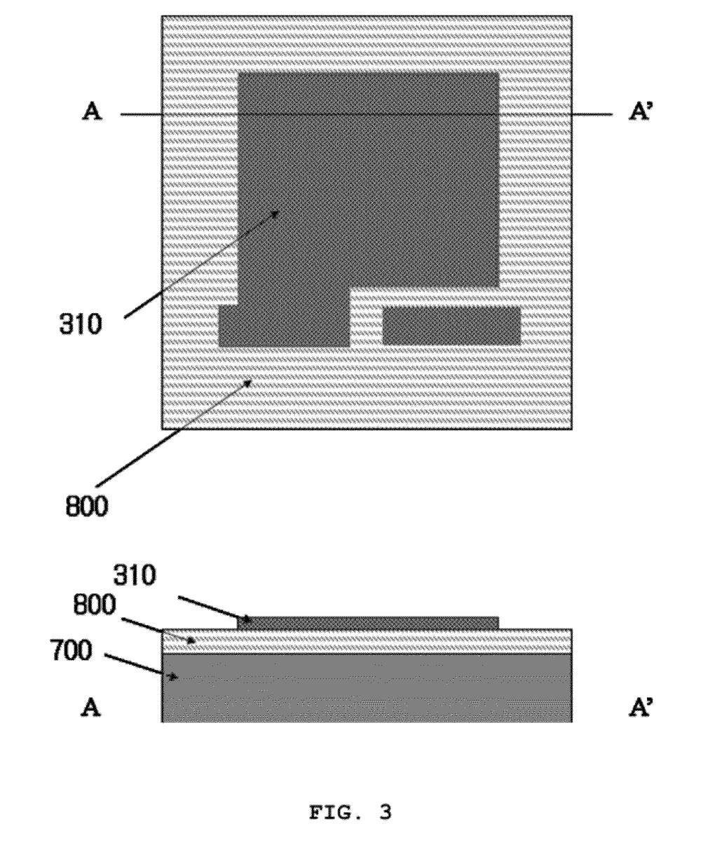

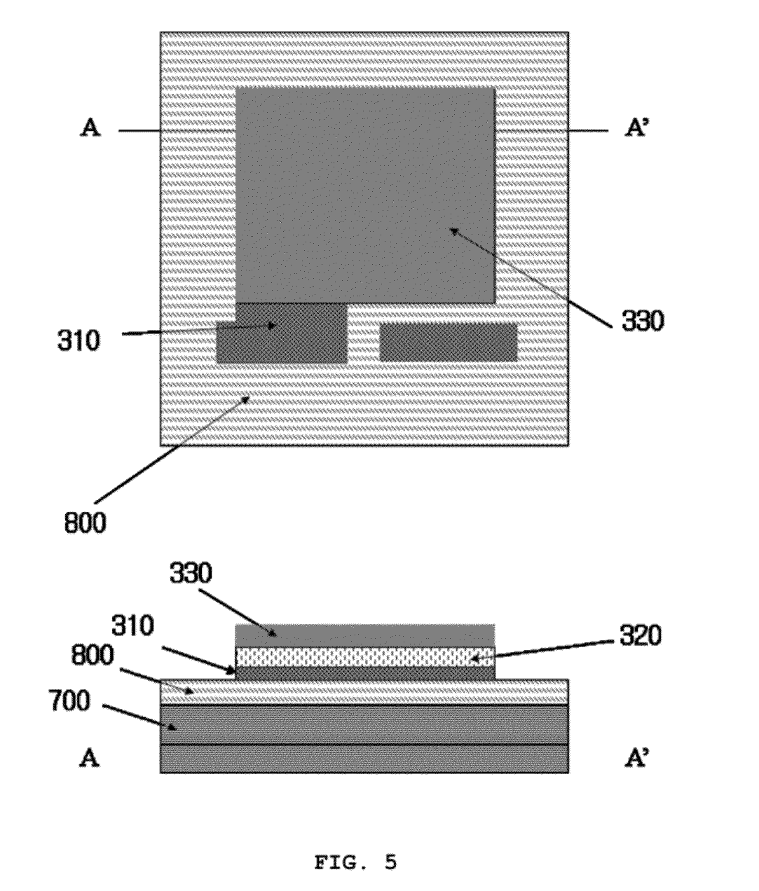

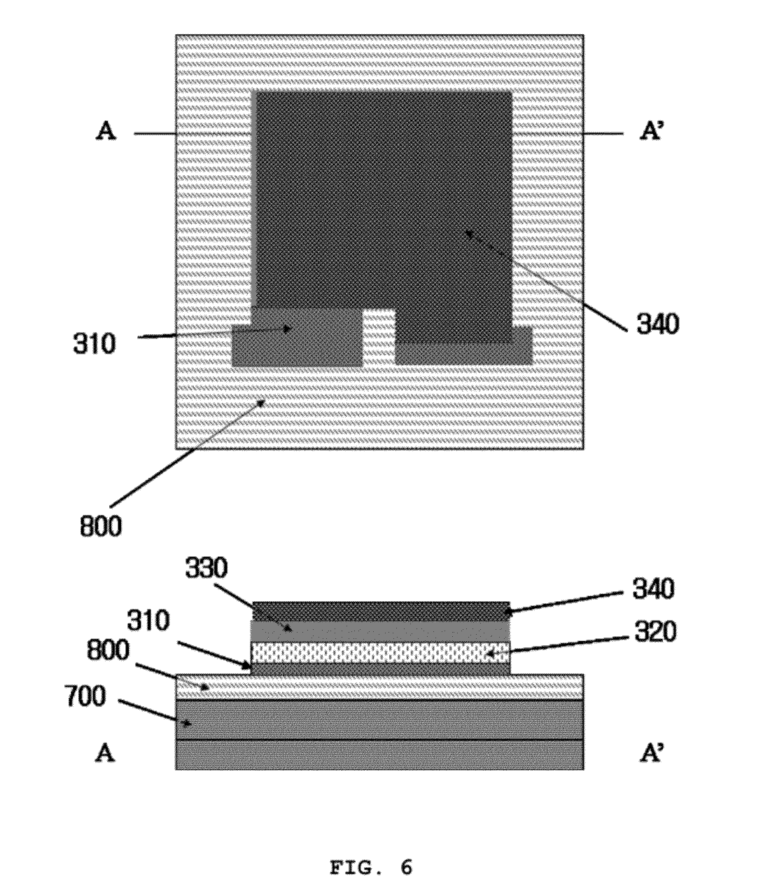

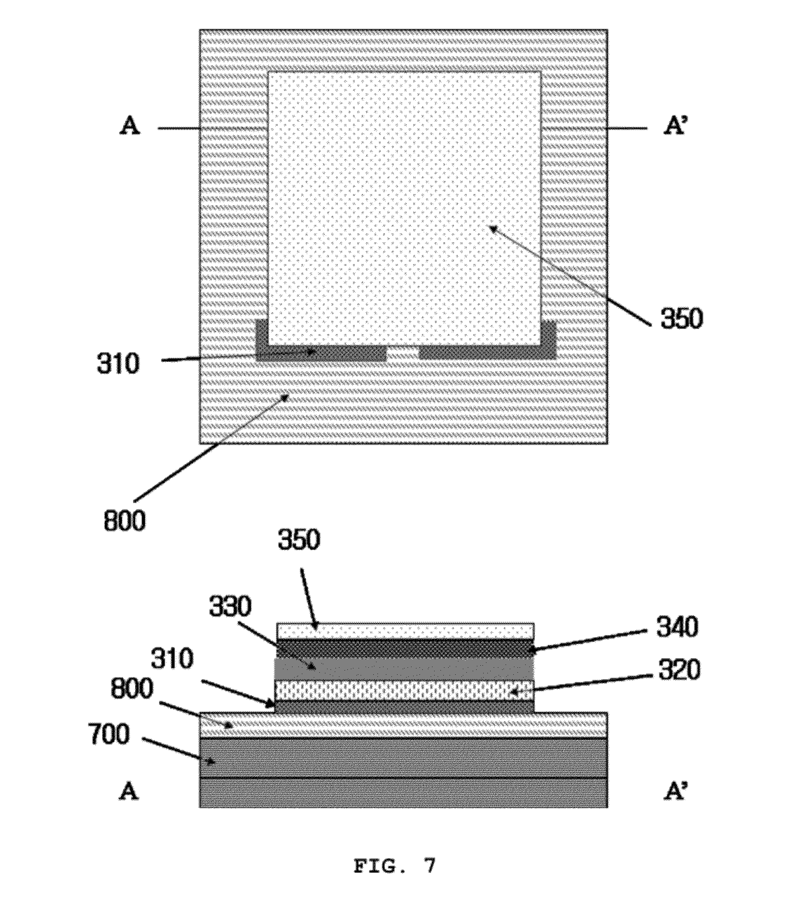

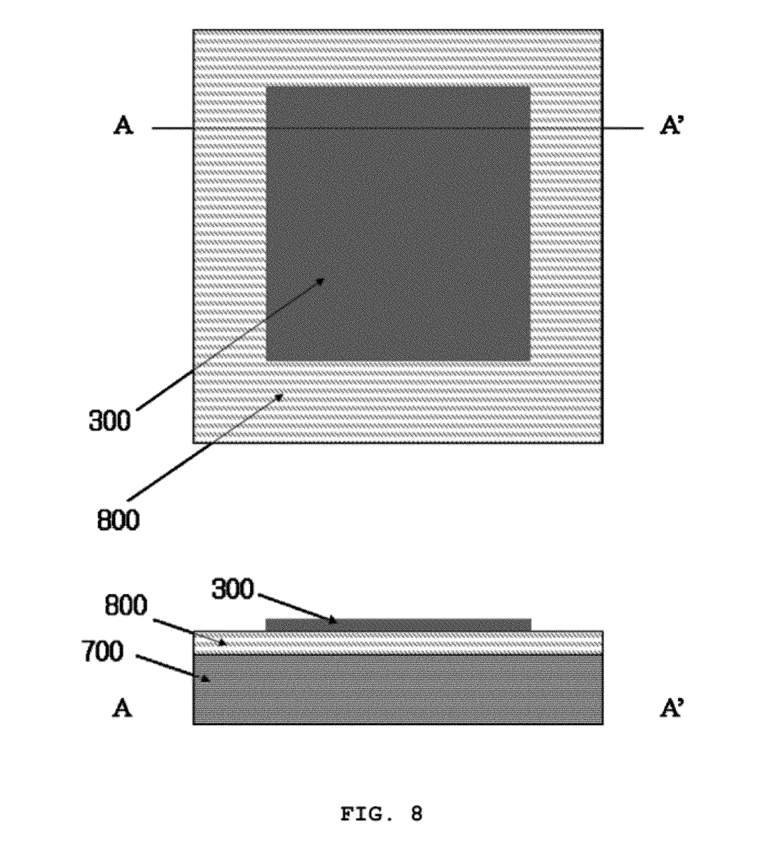

Referring to FIGS. 3-8, a current collector 310, a cathode 320, an electrolyte layer 330, an anode 340 and a packaging material 350 are laminated sequentially on the amorphous silicon layer 800 to form a secondary battery layer 300. However, as described above, the electronic device is not limited to the secondary battery and any type of electronic device that can be fabricated on an amorphous silicon or glass substrate may be fabricated by the method according to the present disclosure.

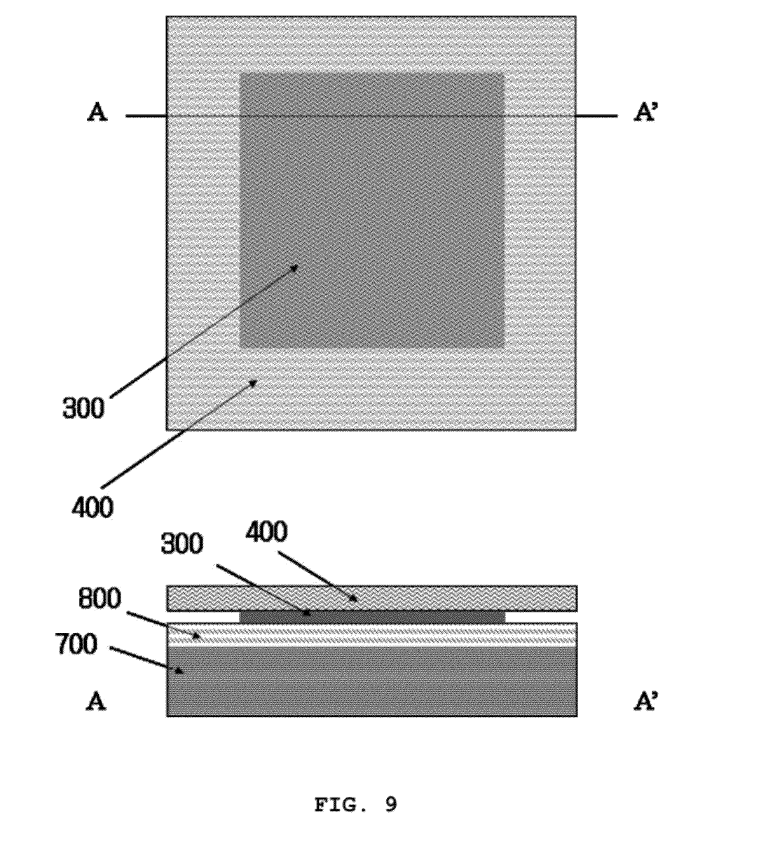

Referring to FIG. 9, the electronic device, i.e. the secondary battery 300, formed on the amorphous silicon layer 800 is contacted with and bonded to a support layer 400. In an exemplary embodiment of the present disclosure, the support layer 400 may comprise polydimethylsiloxane, and an additional bonding layer (not shown) may be formed on the support layer 400 to enhance bonding with the electronic device.

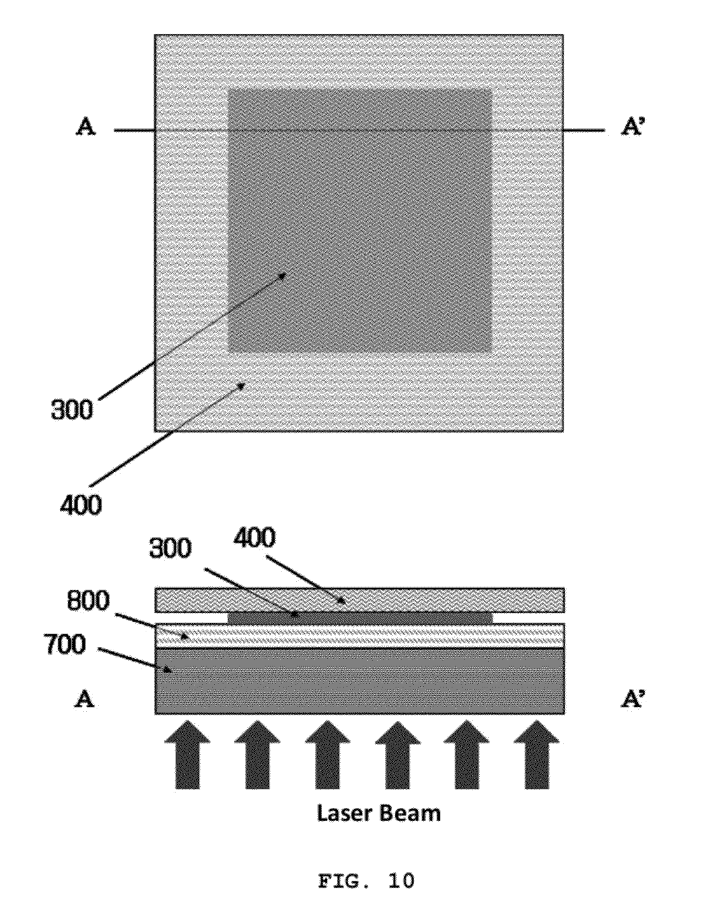

Referring to FIG. 10, a laser beam is irradiated to the back surface of the glass substrate 700. The laser beam passes through the glass substrate 700 and reaches the amorphous silicon layer 800 formed below the electronic device, on the front surface of the glass substrate 700. As a consequence, hydrogen included in the amorphous silicon layer 800 is outgassed and the amorphous silicon layer 800 is released and then removed.

From the secondary battery which is separated from the sacrificial substrate by irradiating the laser beam and then fixed to the bonding layer, a flexible electronic device may be fabricated in two ways, as described below.

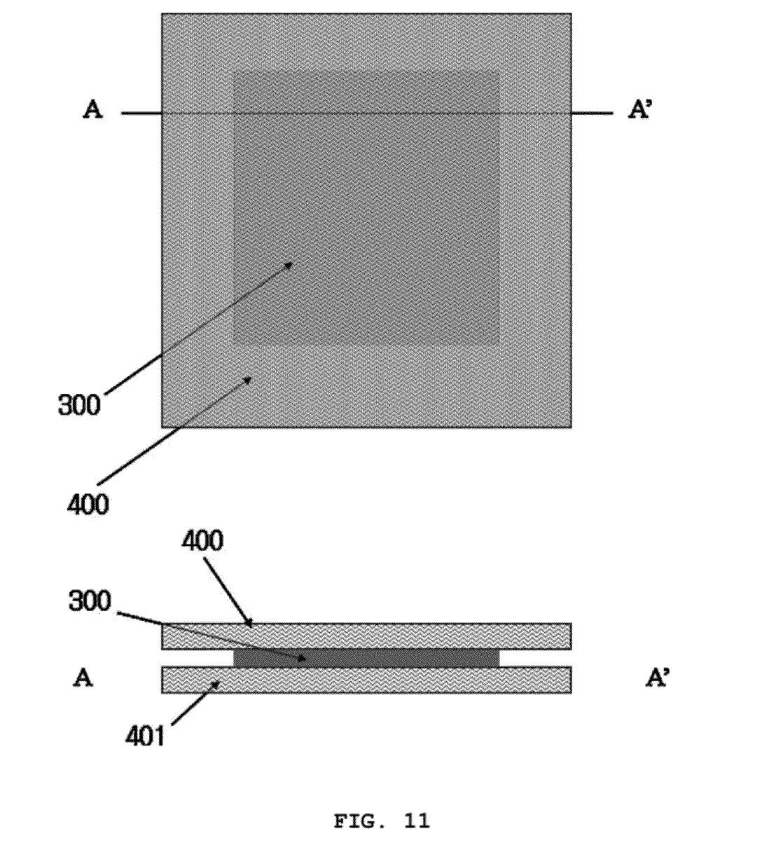

Referring to FIG. 11, another support layer (hereinafter, second support layer) 401 may be bonded at the opposite side of the battery layer 300 with the support layer (hereinafter, first support layer) 400 bonded. As a result, the battery layer transferred after being fabricated on the silicon substrate is inserted between the two polymer material layers. The battery layer 300 forms a neutral mechanical layer in the device.

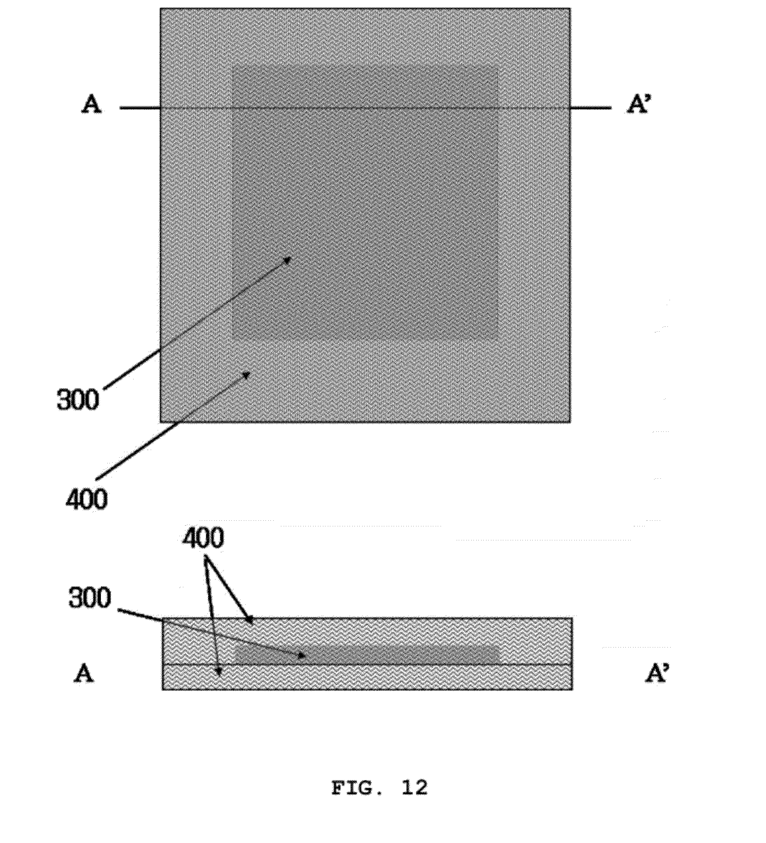

Alternatively, referring to FIG. 12, a material the same as that of the support layer may be coated on the battery layer 300 with the support layer 400 bonded. In this case, the battery layer 300 is inserted into the support layer 400 and is not exposed to outside.

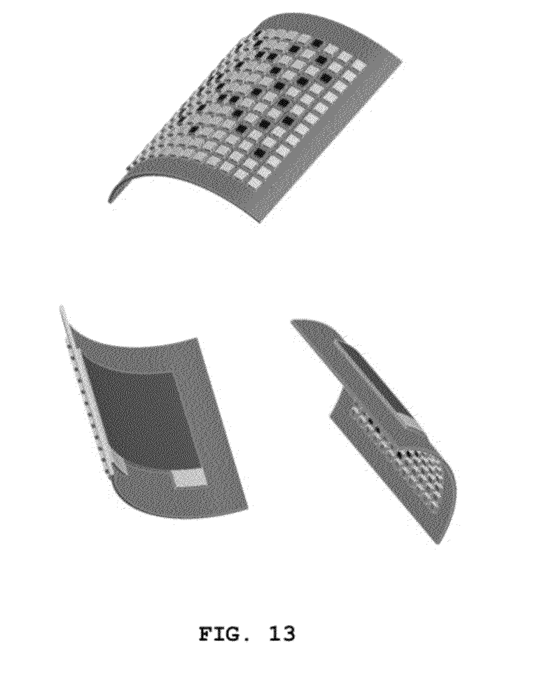

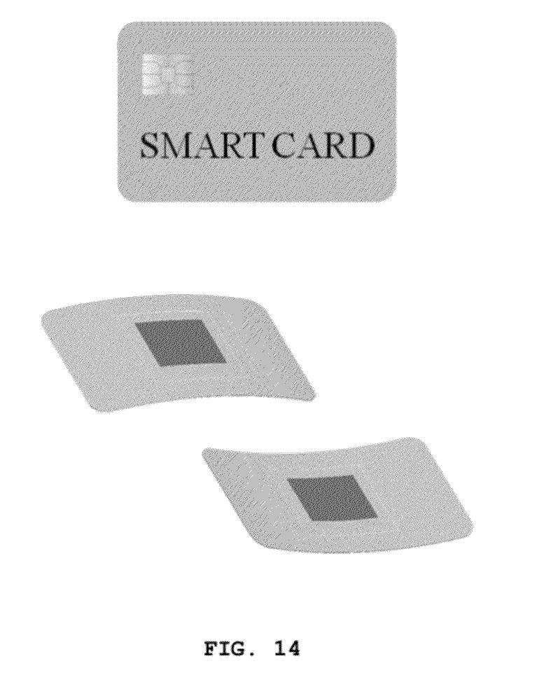

FIGS. 13 and 14 show application examples of the flexible secondary battery according to the present disclosure.

The flexible secondary battery according to the present disclosure may be used as a means of supplying power to a flexible display as in FIG. 13 or as a means of supplying power to a smart card as in FIG. 14.

Another embodiment of the present disclosure relates to a method for fabricating a plastic battery device, comprising fabricating a battery device on a substrate where a semiconductor process can be performed at high temperature and under harsh condition and then removing the substrate. The substrate is called the sacrificial substrate since it not one on which the battery is operated but is removed after the fabrication. That is to say, after the battery layer (i.e. a battery device layer in the form of thin film) is fabricated on the sacrificial substrate, the fabricated battery layer is transferred to a plastic substrate. In another exemplary embodiment of the present disclosure, a supporting substrate is first bonded with the battery layer to prevent deformation of the battery layer such as folding or bending that may occurs after the removal of the sacrificial substrate. Although both the supporting substrate and the sacrificial substrate may be silicon substrates in an exemplary embodiment of the present disclosure, the present disclosure is not limited thereto.

Furthermore, a buffer layer such as an oxide layer may be provided between the sacrificial substrate and the battery layer in order to prevent damage of the device that may occur during the removal of the sacrificial substrate. The oxide layer serves as an etching stop layer by lowering the rate of wet etching.

A method for fabricating a battery device according to an embodiment of the present disclosure may comprise: forming an oxide layer on a sacrificial substrate; forming a battery layer on the oxide layer; forming a silicon layer on the battery layer; removing the sacrificial substrate; and transferring the battery formed on the oxide layer to a plastic substrate. The substrate may be a substrate that can endure the high-temperature battery fabrication process, e.g. a silicon substrate.

Hereinafter, the method for fabricating a battery device according to the present disclosure will be described referring to the attached drawings.

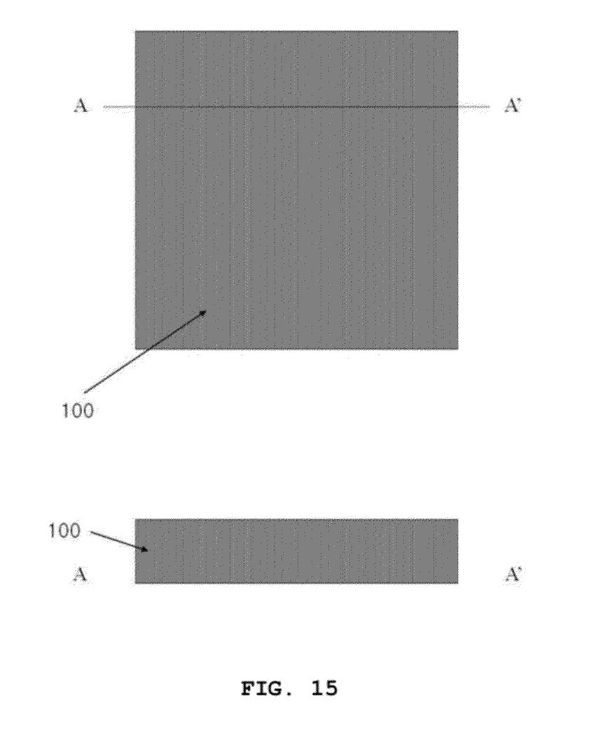

Referring to FIG. 15, a silicon substrate 100 is provided. Specifically, the silicon substrate may be a single-crystalline silicon substrate but is not limited thereto.

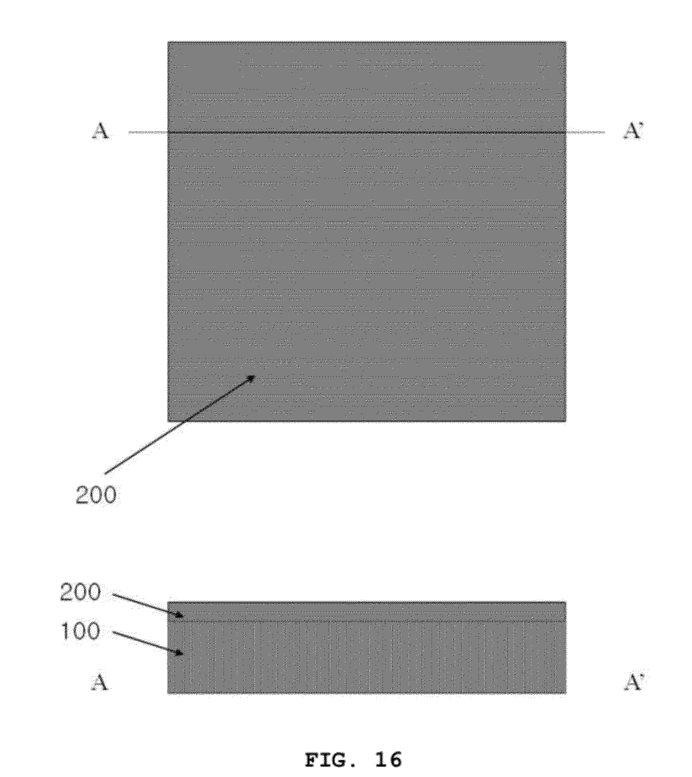

Referring to FIG. 16, a silicon oxide layer 200 is formed on the silicon substrate 100 as the silicon substrate 100 is oxidized. In an exemplary embodiment of the present disclosure, the oxidation may be performed by plasma-enhanced chemical vapor deposition (PECVD), but the present disclosure is not limited thereto.

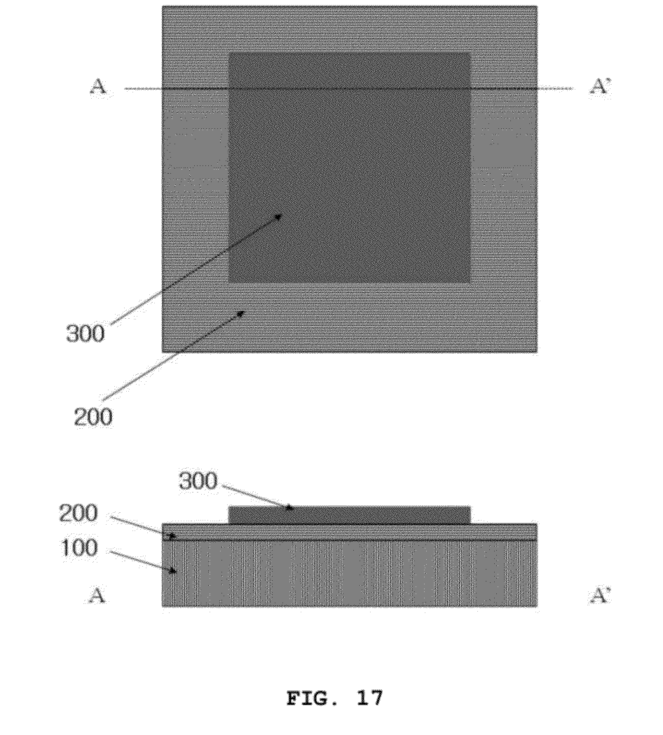

Referring to FIG. 17, a battery layer 300 is formed on the silicon oxide layer 200. In an exemplary embodiment of the present disclosure, the battery may be a solid-state battery, e.g. a thin-film lithium secondary battery comprising a solid electrolyte, but is not limited thereto. And, in an exemplary embodiment of the present disclosure, the battery layer 300 may be a thin-film secondary battery with a basic structure of a battery, consisting of a cathode, an anode and an electrolyte, and having a predetermined height and area.

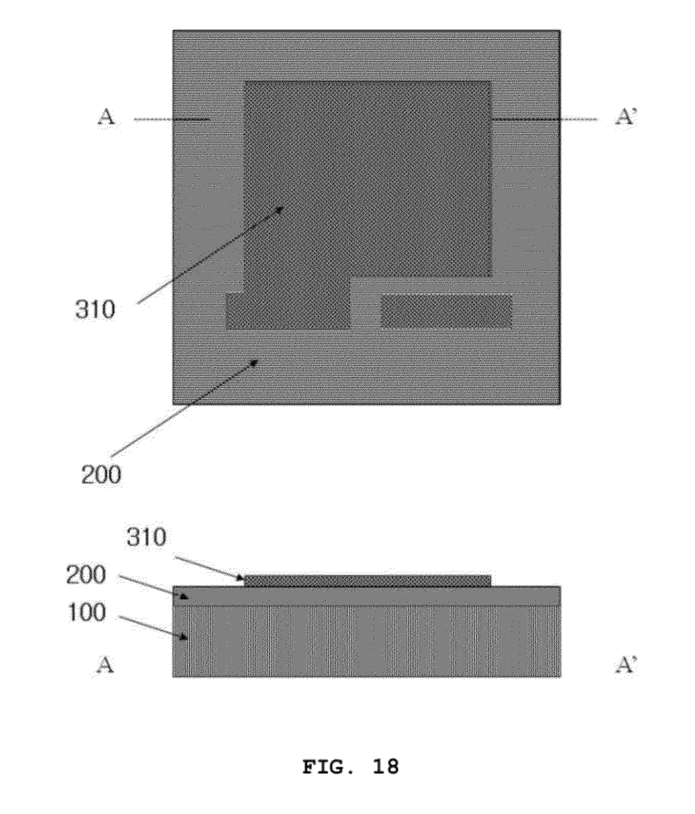

FIGS. 18-22 show the process of fabricating the battery layer 300 in detail.

Referring to FIG. 18, a current collector 310 is formed first. The current collector collects the current generated from the battery and transfers it to outside. It may comprise a metal material such as platinum (Pt), aluminum (Al), copper (Cu), etc. However, any material that can transfer the current without interrupting the reversible reaction of lithium by reacting with an electrode active material or the lithium may be used, without particular limitation. A bonding layer (not shown) comprising, for example, titanium (Ti) or chromium (Cr) may be provided between the current collector and the substrate to improve adhesion.

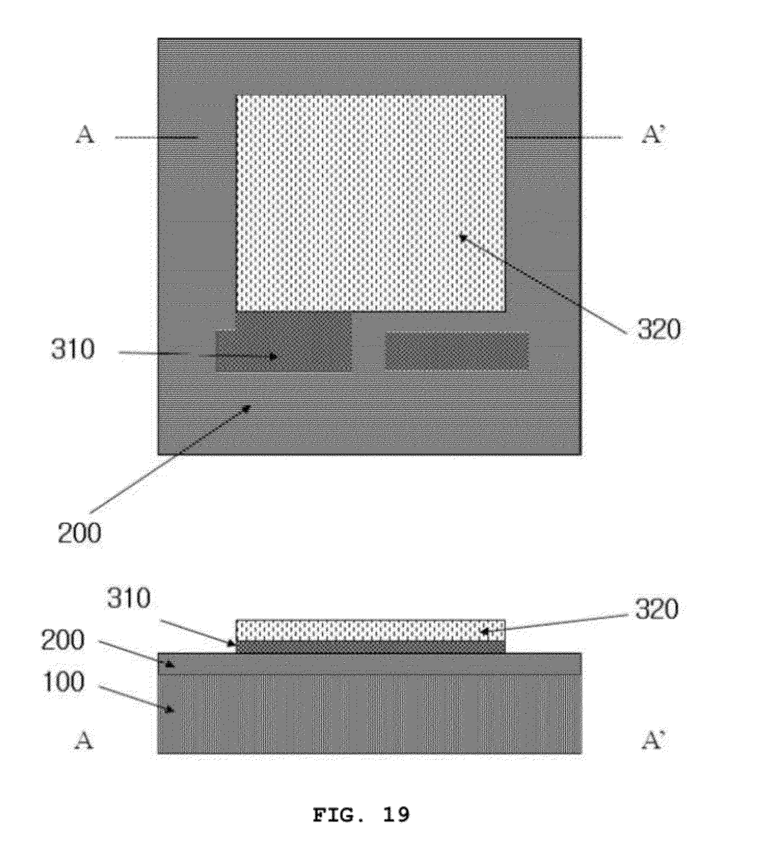

Referring to FIG. 19, an electrode material is deposited on the current collector 310 to form a cathode 320. When a lithium secondary battery is to be fabricated, lithium oxides including layered materials such as LiCoO₂, LiNiO₂, etc., spinel materials such as LiMn₂O₄, etc., olivine materials such as LiFePO₄, etc., silicate materials such as Li₂FeSiO₄, etc., or the like may be used for the cathode.

The lithium oxide used as the cathode material is usually deposited on the current collector by sputtering and then crystallized by heat treatment. For example, a rapid thermal process generally requires heating to 500° C. or above for 10 minutes or longer, and a furnace heating requires heating to 500° C. or above for 2 hours or longer. In the present disclosure, such heat treatment can be performed easily since the silicon substrate has superior heat resistance.

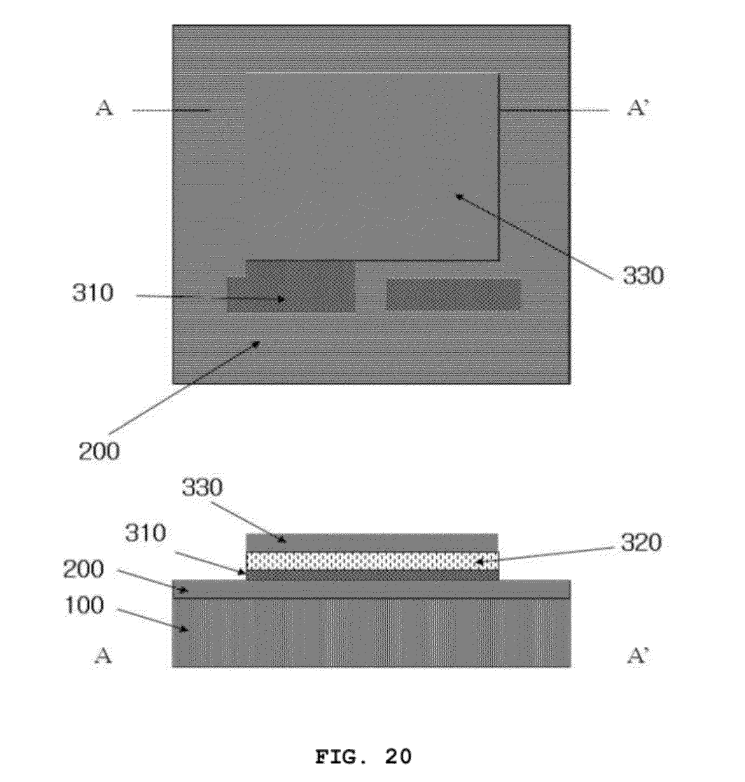

Referring to FIG. 20, an electrolyte layer 330 is formed on the cathode 320. In an exemplary embodiment of the present disclosure, the electrolyte of the electrolyte layer 330 may be a solid electrolyte such as lithium phosphorus oxynitride (LiPON). However, any one that allows for conduction of electricity through movement of lithium ions may be used without particular limitation.

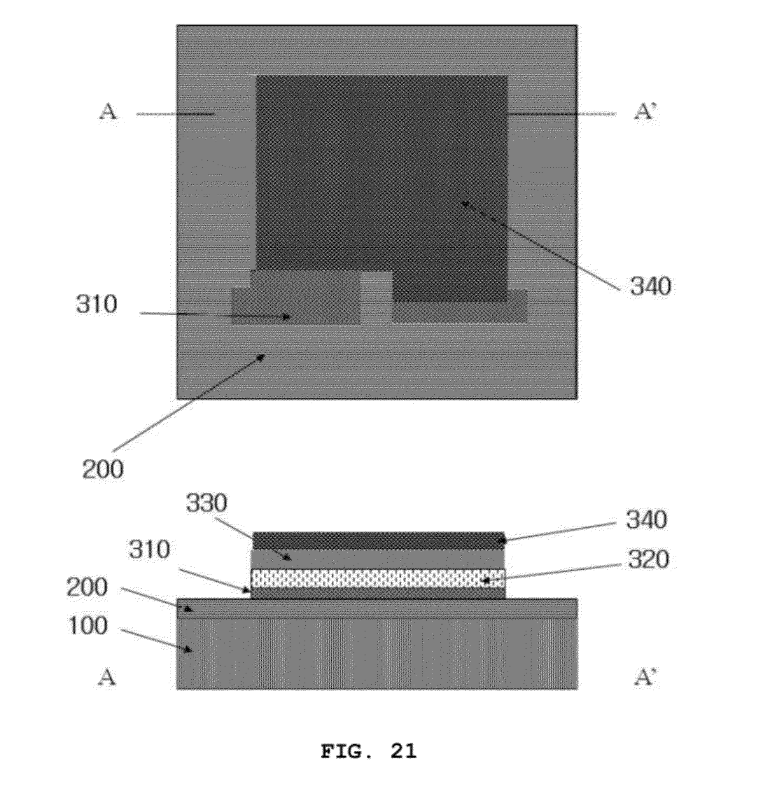

Referring to FIG. 21, an anode 340 is formed on the electrolyte layer 330. In general, lithium metal, lithium alloy, carbon material, silicon, silicon alloy, or the like may be used for the anode material. However, any material allowing for reversible intercalation and deintercalation of lithium may be used without particular limitation.

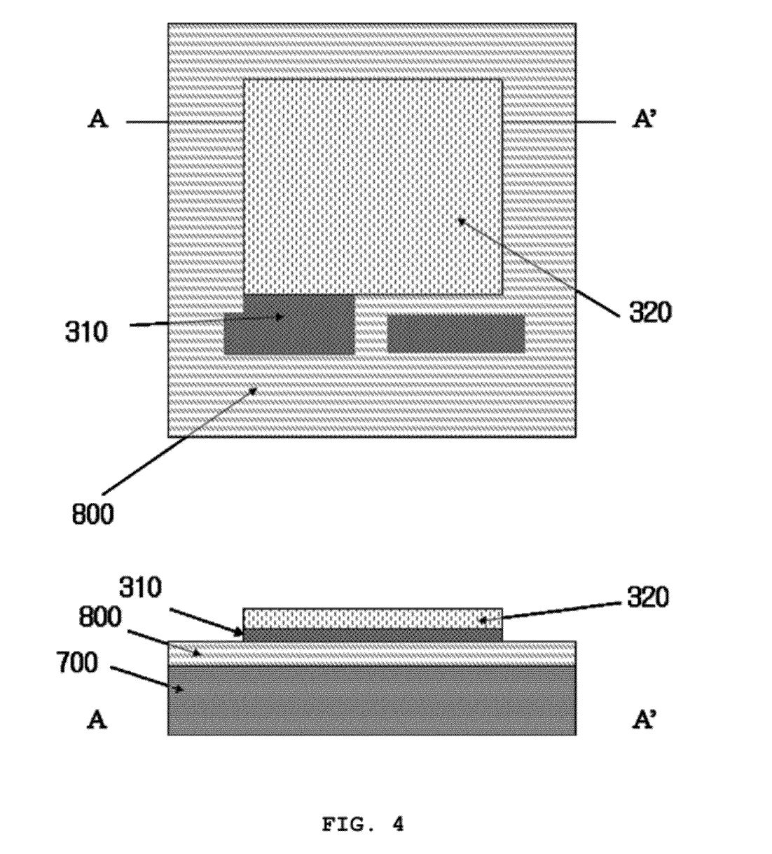

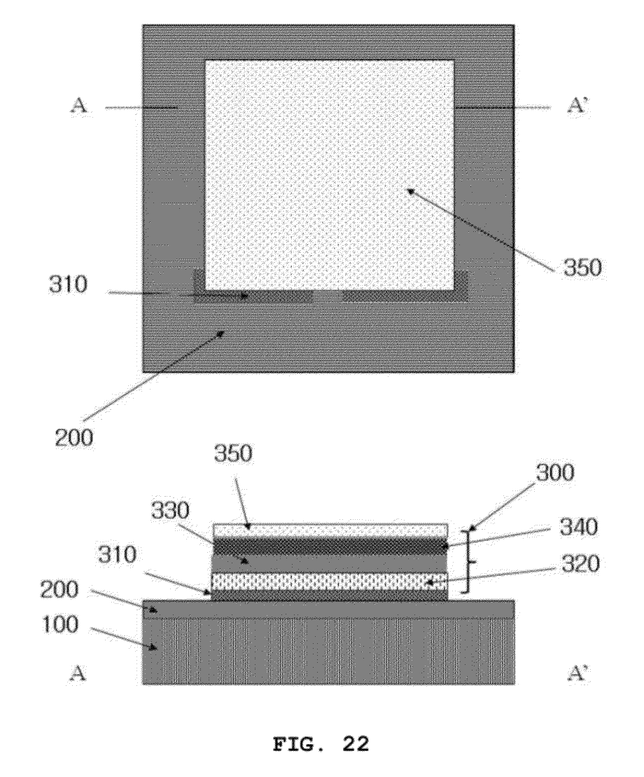

Referring to FIG. 22, a packaging material layer 350 is formed on the anode 340. In an exemplary embodiment of the present disclosure, the packaging material layer 350 prevents unwanted reactions that deteriorate battery performance by preventing contact of the electrode material with outside. Any material commonly used in the art may be included in the packaging material layer 350. Through the processes shown in FIGS. 4-8, the battery layer 300 comprising the current collector 310, the cathode 320, the electrolyte layer 330, the anode 340 and the packaging material layer 350 is formed. However, the battery layer 300 may have any other structure as long as electric current can be stored and generated. The battery layer 300 of the present disclosure prepared through the processes of FIGS. 4-8 may have a smaller area than that of the silicon substrate 100 therebelow.

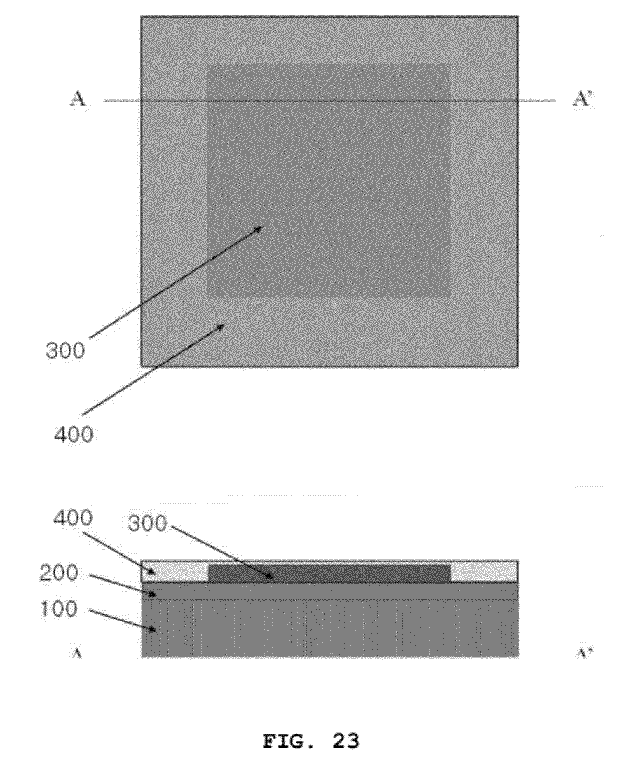

Referring to FIG. 23, a first bonding layer 400 is coated on the battery layer 300. The first bonding layer 400 also covers the portion of the silicon oxide layer 200 on which the battery layer 300 is not formed. The height of the first bonding layer 400 may be larger than that of the battery layer 300, so that the first bonding layer 400 completely covers the battery layer 300. In an exemplary embodiment of the present disclosure, the bonding layer 400 may comprise a thermosetting epoxy resin, but is not limited thereto.

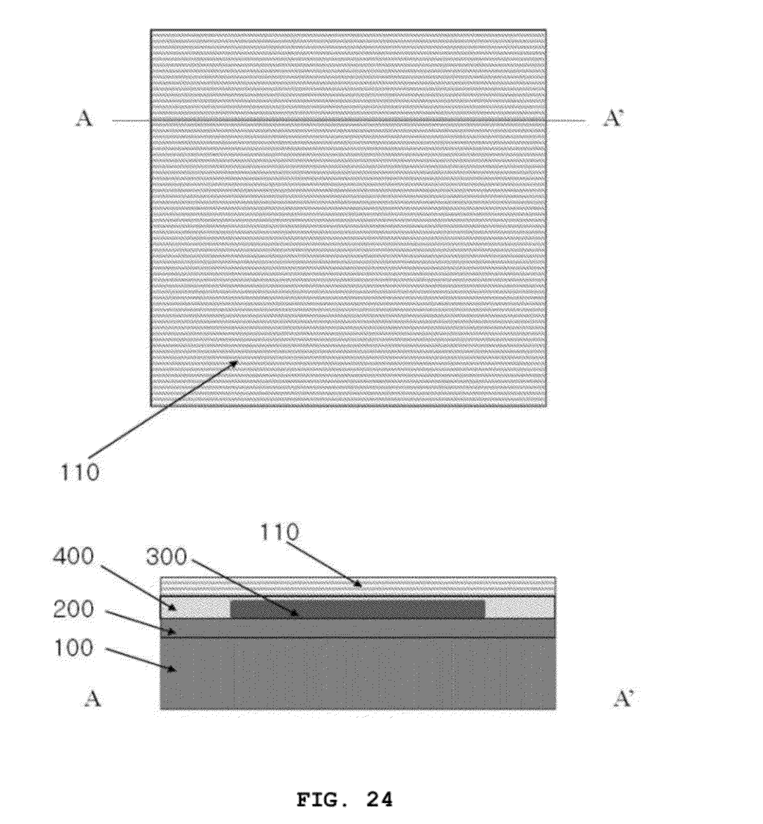

Referring to FIG. 24, another silicon substrate 110 is provided on the bonding layer 400 completely covering the battery layer 300. In an exemplary embodiment of the present disclosure, after the bonding layer 400 is slightly hardened on a heating plate, it may be completely hardened after placing the silicon substrate 110 thereon. The upper silicon substrate 110 is distinguished from the lower silicon substrate 100. Hereinafter, the lower silicon substrate 100 is called a first silicon substrate and the upper silicon substrate 110 is called a second silicon substrate. As described earlier, the second silicon substrate 110 is physically bonded with the battery layer 300 and prevents physical deformation of the battery layer 300 that may occur as the lower substrate 100 is removed. That is to say, in the method for fabricating a plastic battery device according to the present disclosure, the silicon substrates are provided on both sides of the battery and then removed sequentially.

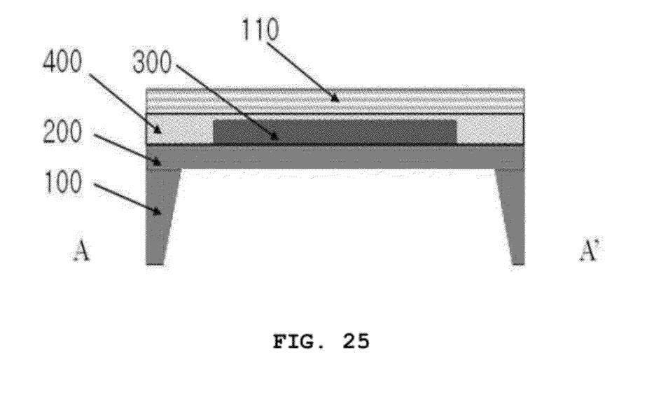

Referring to FIG. 25, the first silicon substrate 100 is removed. In an exemplary embodiment of the present disclosure, the lower silicon substrate 100 may be removed by wet etching. As a result of wet etching, the battery is provided on silicon oxide layer 200, not on the first silicon substrate 100. This is because the silicon oxide layer 200 is etched at low rate during the wet etching. In the absence of the silicon oxide layer 200, the battery device 300 is directly exposed to the etchant. In an exemplary embodiment of the present disclosure, the first silicon substrate is remained at the edge in order to prevent penetration of the etchant into the battery layer. That is to say, since the etchant (e.g., KOH, tetramethylammonium hydroxide (TMAH), etc.) may penetrate between the silicon oxide layer 200 and the battery layer 300 during wet etching, the edge portion of the first silicon substrate 100 is remained to prevent the etchant from crossing the substrate. However, any configuration allowing for the removal of at least the portion of the battery layer 300 corresponding to the lower silicon substrate 100 by etching is included in the scope of the present disclosure, without being limited thereto. The first silicon substrate 100 at the edge portion is removed, for example, by grinding.

Referring to FIG. 25, after the first silicon substrate is removed, the battery layer 300 is still in contact and bonded with the second silicon substrate 110. Subsequently, the second silicon substrate 110 is bonded with a transfer layer (not shown). The transfer layer may be any substrate or flat member capable of transferring the battery device to a plastic substrate. For example, the transfer layer may be a silicon substrate or a polydimethylsiloxane (PDMS) layer. In an exemplary embodiment of the present disclosure, PDMS coated with an adhesive resin such as epoxy or SU-8 may be used as the transfer layer.

Then, the battery layer 300 is transferred to a plastic substrate by the transfer layer bonded with the second silicon substrate 110.

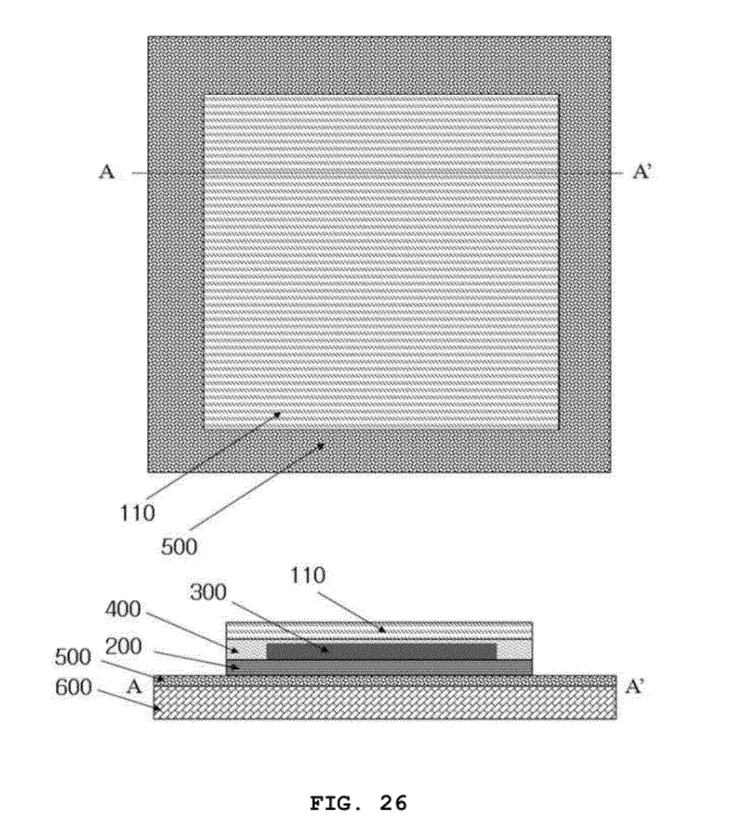

Referring to FIG. 26, the plastic battery comprises a lower plastic substrate 600, a second bonding layer 500 on the lower plastic substrate 600, and a silicon oxide layer 200 contacting and bonded with the second bonding layer 500. The battery layer 300 is provided on the silicon oxide layer 200, and the second silicon substrate 110 is provided on the battery layer 300 and the first bonding layer 400 is provided at the side thereof.

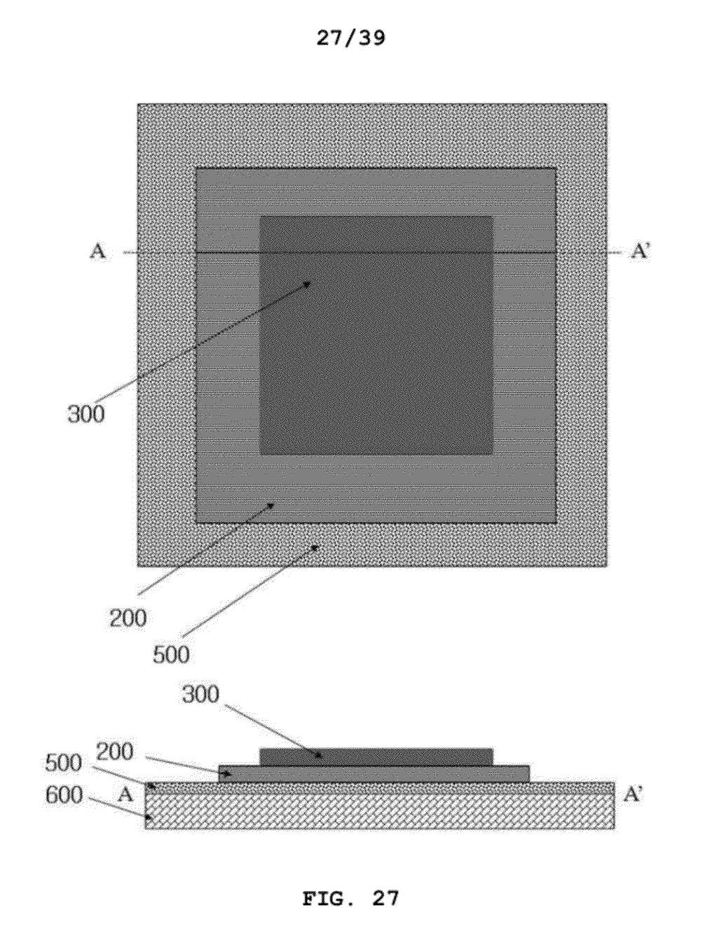

Referring to FIG. 27, after the battery device 300 is transferred to the plastic substrate 600, the first bonding layer and the second silicon substrate are removed. As a result, the plastic battery device with the battery layer 300 exposed on the plastic substrate 600 is obtained. In an exemplary embodiment of the present disclosure, the second silicon substrate 110 and the first bonding layer 400 may be separated and removed from the battery device 300 by dissolving the first bonding layer comprising epoxy resin with an organic solvent such as acetone.

The scope of the present disclosure is not limited to the aforesaid type or material of the device. The present disclosure is applicable to any device that is fabricated on a silicon substrate via a semiconductor process, without being limited to the above description.

In the method for fabricating a plastic secondary battery according to the present disclosure, the secondary battery device layer is directly formed on the plastic substrate where a semiconductor process cannot be performed at high temperature and under harsh condition. In order to overcome the limitation of the substrate and to improve the performance of the device layer, annealing is performed using laser or a flash lamp.

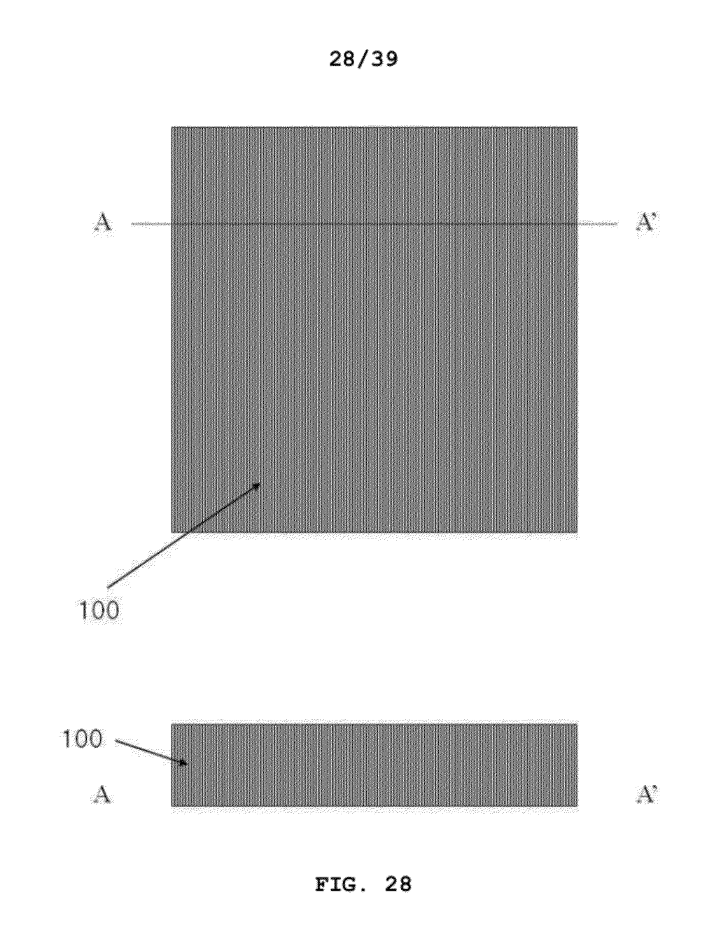

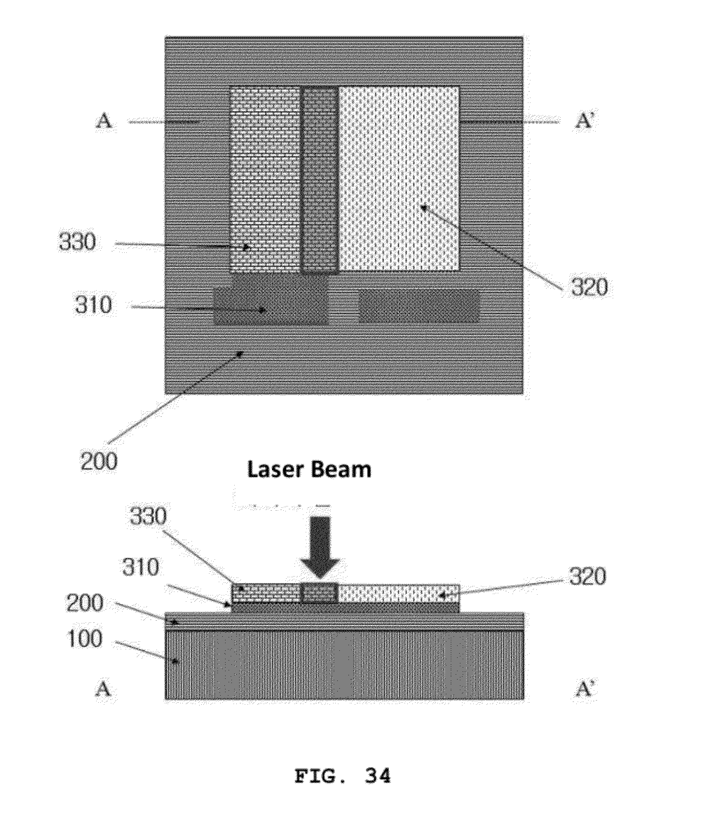

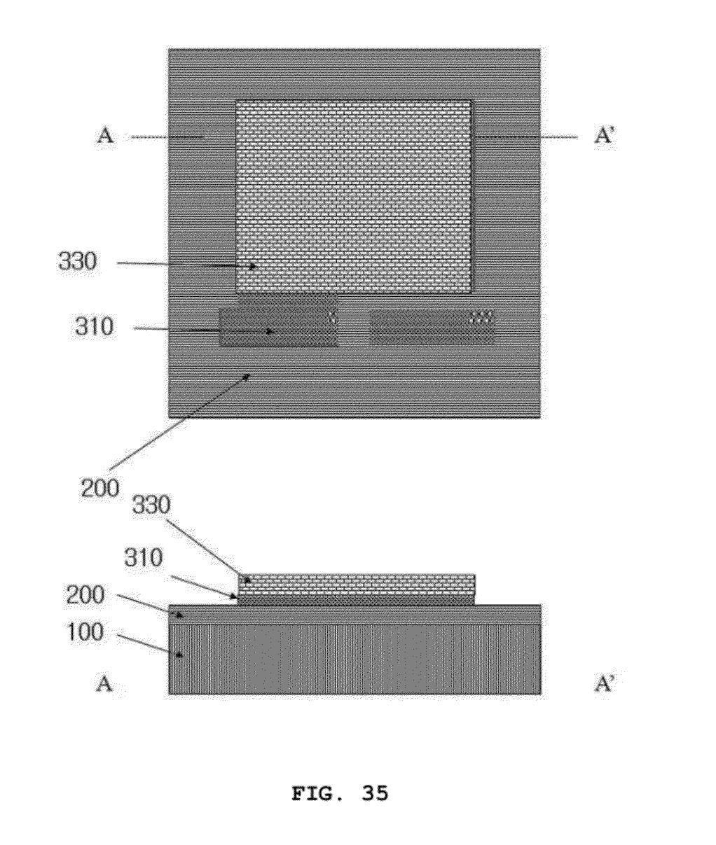

FIGS. 28-39 show a process of fabricating a plastic secondary battery according to another exemplary embodiment of the present disclosure.

Referring to FIG. 28, a plastic substrate 100 is provided. The plastic substrate 100 may comprise any plastic material having flexible properties such as a PCB substrate.

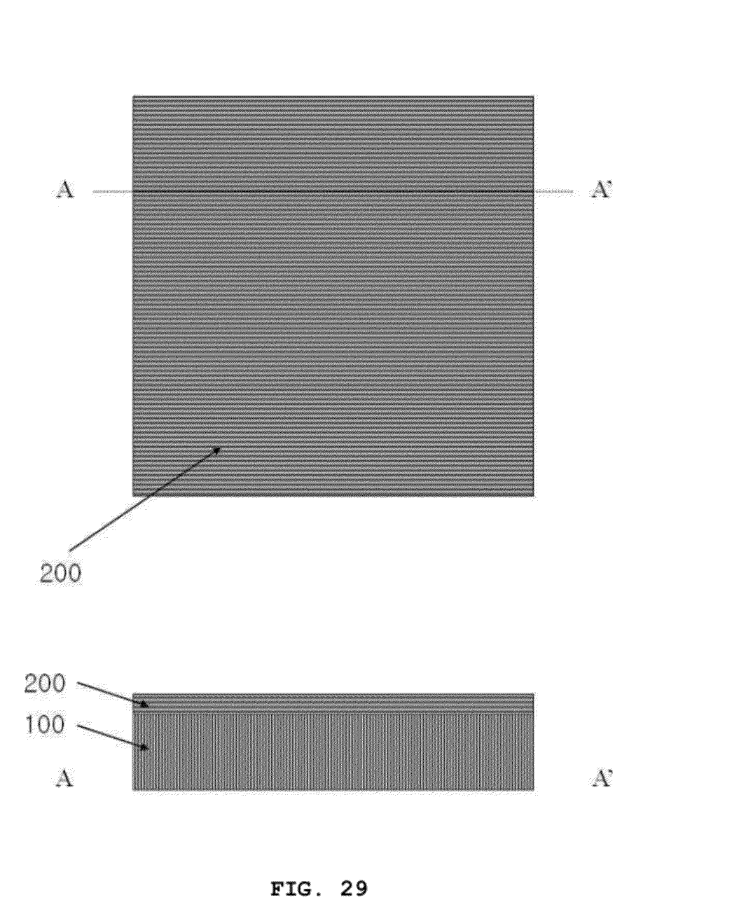

Referring to FIG. 29, a silicon oxide layer 200 is formed on the plastic substrate 100. The silicon oxide layer 200 may be formed by chemical vapor deposition. The silicon oxide layer 200 is formed to provide sufficient adhesion for a secondary battery as a buffer layer between the plastic substrate and the device and to prevent damage to the plastic substrate during laser annealing. The silicon oxide layer 200 may be selected adequately according to the type of a current collector 310 formed on the plastic substrate. In an exemplary embodiment of the present disclosure, a buffer layer 200 may be used. The silicon oxide layer 200 may have a thickness of 100-500 nm. When the thickness is smaller, it will be difficult to prevent thermal and physical damage. And, when the thickness is larger, flexibility or other properties of the substrate may be deteriorated.

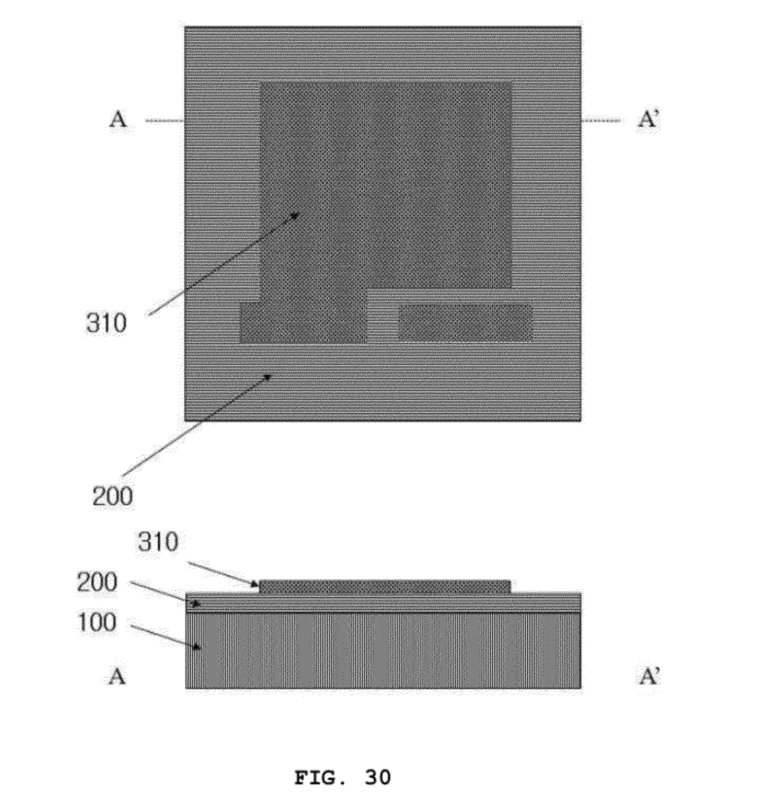

Referring to FIG. 30, a current collector 310 is formed on the silicon oxide layer 200 as a thin film. The current collector collects the current generated from the secondary battery and transfers it to outside. It may comprise a metal material such as platinum (Pt), aluminum (Al), copper (Cu), etc. However, any material that can transfer the current without interrupting the reversible reaction of lithium by reacting with an electrode active material or the lithium may be used, without particular limitation. A bonding layer (not shown) comprising, for example, titanium (Ti) or chromium (Cr) may be provided between the current collector 310 and the silicon oxide layer 200 to improve adhesion.

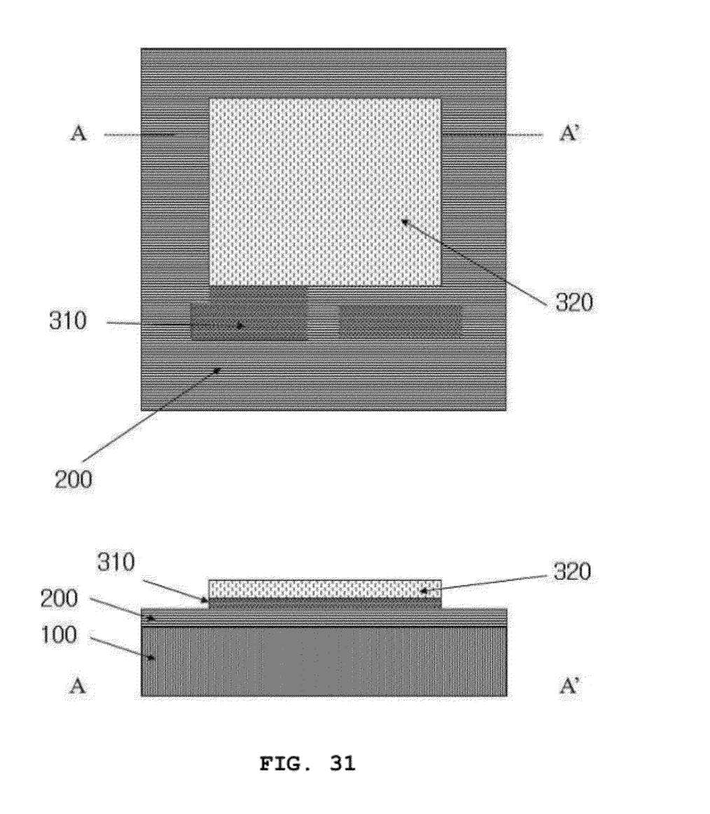

Referring to FIG. 31, an electrode material is deposited on the current collector 310 to form a cathode 320. When a lithium secondary battery is to be fabricated, lithium oxides including layered materials such as LiCoO₂, LiNiO₂, etc., spinel materials such as LiMn₂O₄, etc., olivine materials such as LiFePO₄, etc., silicate materials such as Li₂FeSiO₄, etc., or the like may be used for the cathode. The lithium oxide used as the cathode material is usually deposited on the current collector 310 by sputtering and then crystallized by heat treatment. For example, a rapid thermal process generally requires heating to 500° C. or above for 10 minutes or longer, and a furnace heating requires heating to 500° C. or above for 2 hours or longer. However, the lower plastic substrate cannot endure such processing conditions. Thus, the present disclosure presents an annealing process using laser instead of the heat treatment at high temperature.

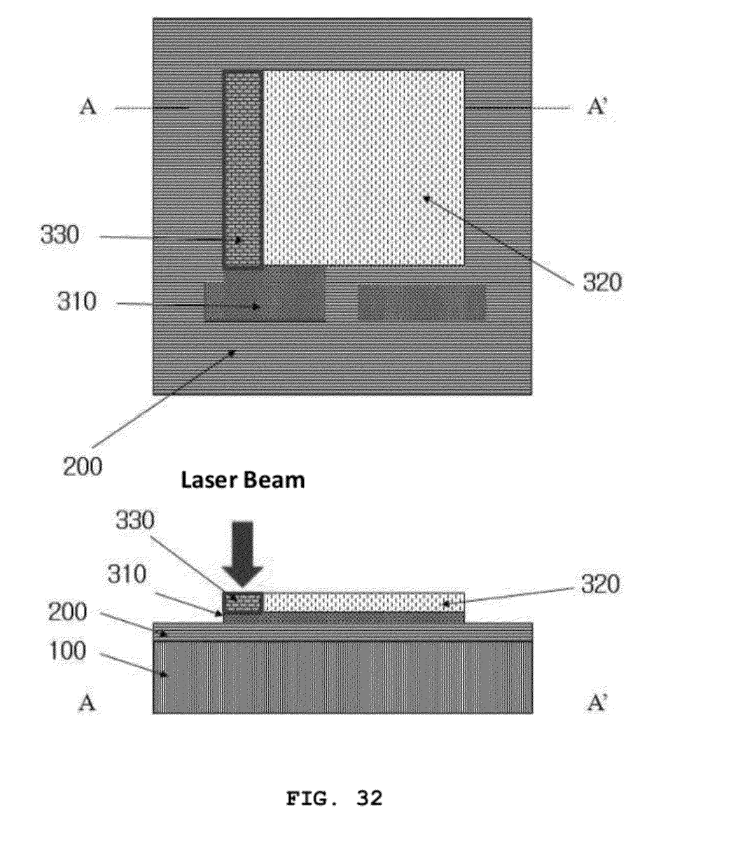

Referring to FIG. 32, laser beam is irradiated using a laser generator or light is irradiated to the cathode 320 using a flash lamp. The cathode is heated by the laser or light irradiated from the laser generator or the flash lamp and crystallized (annealing by light energy). In an exemplary embodiment of the present disclosure, the cathode may be heat-treated by two means, one of them being laser. Since the laser applies thermal energy to the cathode 320 within a very short time of a few nanoseconds, thermal deformation of the plastic substrate 100 can be prevented. Also, the buffer layer 200 functions as a buffer layer of absorbing physical shock effect resulting from the laser irradiation. The portion where the laser is irradiated may be in the form of any of spot, line or plane. Referring to FIG. 32, the laser beam is irradiated to a portion 330 of the cathode 320 and the cathode is crystallized. The energy density of the laser may be in the range of 10-2,000 mJ/cm², although being different according to the thin-film deposition method or substrate temperature during the deposition. For example, when the sol-gel method is used, crystallization may be achieved with an energy density of about 50-300 mJ/cm² because the initial degree of crystallinity is high. When the sputtering is used, 100% crystallization may be achieved with an energy density of about 300-1500 mJ/cm² because the degree of crystallinity may be relatively low. During the annealing by irradiation of the laser beam, the temperature of the substrate irradiated with the laser beam may be 400° C. or lower, more specifically 300° C. or lower. The laser annealing may be performed in the air or under gas (oxygen, nitrogen, argon, etc.) atmosphere to avoid unwanted reactions. Also, it may be performed under ambient or elevated pressures. During the crystallization, it may be necessary to perform heat treatment at higher temperatures depending on the kind or state of oxide. In this case, it may be impossible to anneal the plastic substrate. However, the crystallization condition may be satisfied without having to increase the temperature when the crystallization is performed under high pressure.

In an exemplary embodiment of the present disclosure, the high pressure may be 5 atm or higher, more specifically 10-250 atm or higher. The high-pressure condition allows for easier crystallization by facilitating recombination of seeds with melts.

In another exemplary embodiment of the present disclosure, a flash lamp may be used as a source of light energy. The flash lamp supplies thermal energy in millisecond scales and crystallizes the cathode material, unlike focusing of localized energy (more accurately, localized thermal energy) by irradiating laser in nanosecond scales. Accordingly, the advantages of the flash lamp, i.e. large irradiation area, millisecond-scale irradiation time, and low manufacturing cost, can be utilized to anneal a cathode of large area. In an exemplary embodiment of the present disclosure, a plurality of flash lamps that generated light energy from applied electrical energy may be used for the annealing process. The flash lamp may be a xenon (Xe) lamp, but is not limited thereto.

Although heat treatment using the laser or the flash lamp was described above, any method of heating and crystallizing the cathode formed on the plastic substrate using light energy is included in the scope of the present disclosure. Hereinafter, the processes following crystallization using laser will be described.

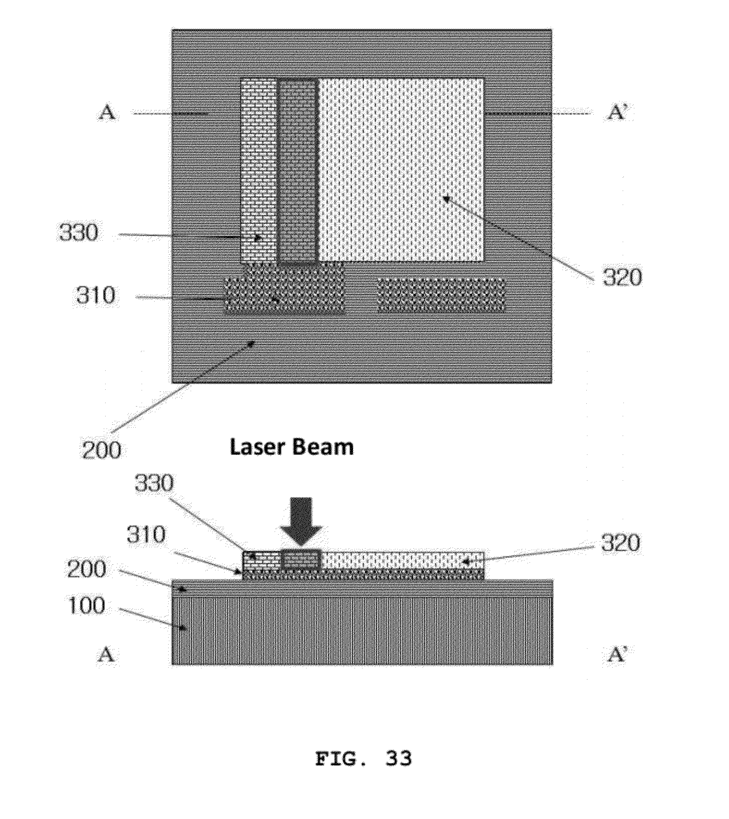

Referring to FIGS. 33-35, a laser beam is irradiated sequentially on the entire surface of the cathode 320 to crystallize the cathode. However, when a flash lamp capable of irradiating light to a large area is used, the entire surface of the battery can be crystallized through only a single heat-treatment process as described above.

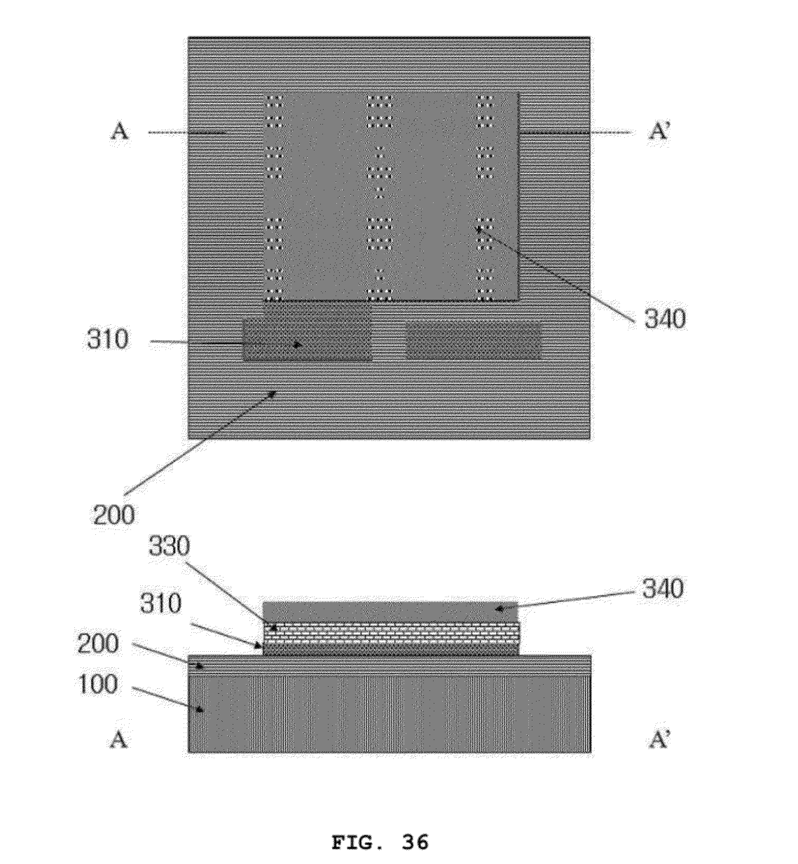

Referring to FIG. 36, an electrolyte layer 340 is formed on the cathode 330 crystallized by the laser beam. In an exemplary embodiment of the present disclosure, the electrolyte of the electrolyte layer 340 may be a solid electrolyte such as lithium phosphorus oxynitride (LiPON).

However, any material that allows for conduction of electricity through movement of lithium ions may be used without particular limitation.

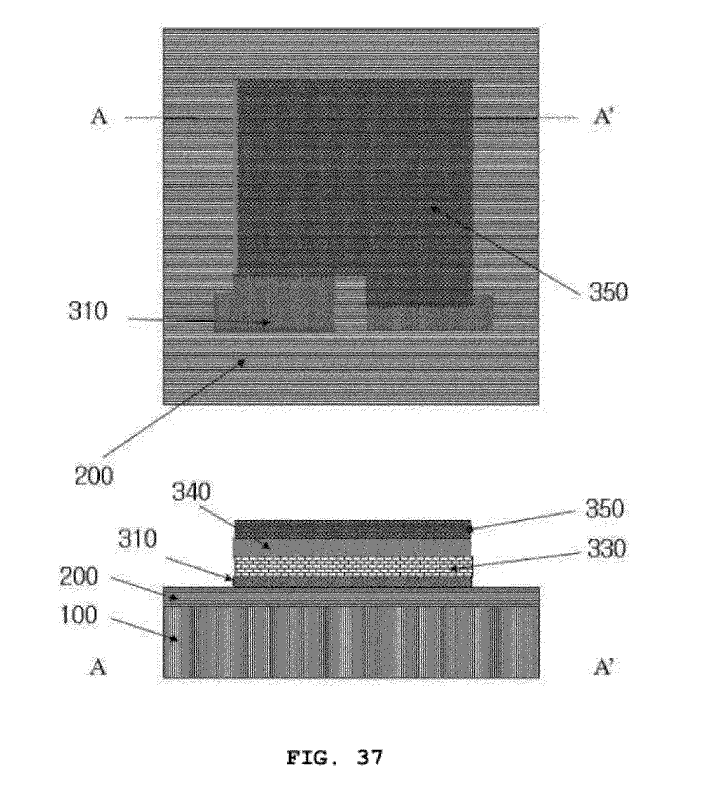

Referring to FIG. 37, an anode 350 is formed on the electrolyte layer 340. In general, lithium metal, lithium alloy, carbon material, silicon, silicon alloy, or the like may be used for the anode material. However, any material allowing for reversible intercalation and deintercalation of lithium may be used without particular limitation.

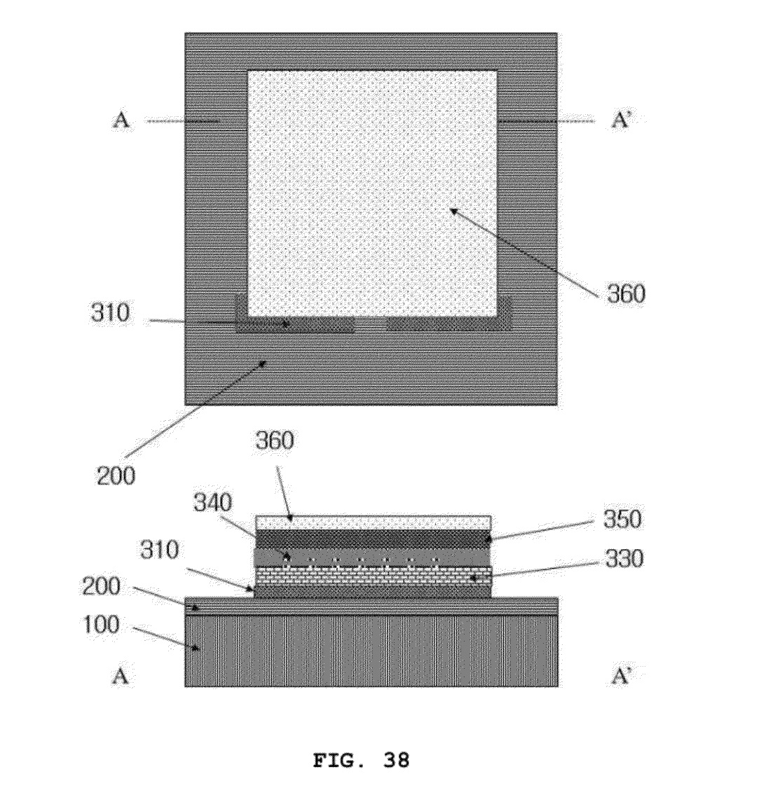

Referring to FIG. 38, a packaging material layer 360 is formed on the anode 350. In an exemplary embodiment of the present disclosure, the packaging material layer 360 prevents unwanted reactions that deteriorate battery performance by preventing contact of the electrode material with outside. Any material commonly used in the art may be included in the packaging material layer 360.

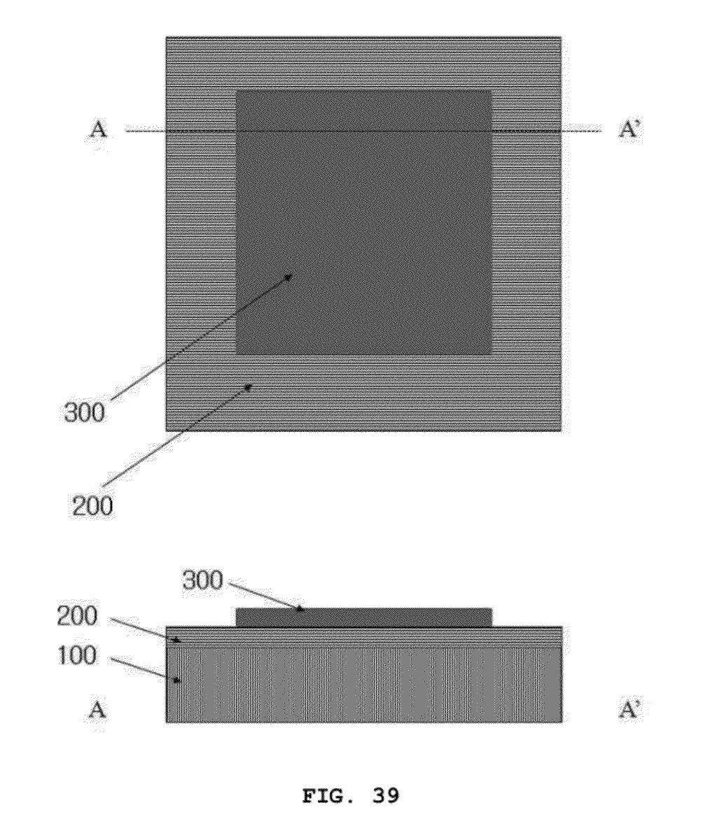

Referring to FIG. 39, through the processes shown in FIGS. 1-11, the secondary battery 300 is fabricated on the plastic substrate 100. A buffer layer 200 for reducing heat transfer by the laser treatment and absorbing physical shock caused by the laser irradiation is provided between the plastic substrate 100 and the secondary battery 300. In an exemplary embodiment of the present disclosure, the buffer layer 200 may comprise silicon oxide, but is not limited thereto.

In accordance with the present disclosure, an electronic device is fabricated on a sacrificial substrate transparent to laser. An amorphous silicon layer is provided between the sacrificial substrate and the electronic device as a separation layer. As hydrogen included in the amorphous silicon layer is outgassed by laser irradiation, the sacrificial substrate can be separated from the electronic device. Accordingly, the present disclosure can easily solve the problem of the wet etching process for separation and allows for fabrication of the flexible electronic device in an economical way. Since the method for fabricating a plastic secondary battery according to the present disclosure involves formation of the secondary battery directly on a plastic substrate, it is economically advantageous over the existing technique of fabricating the device on a silicon substrate and then transferring it. Furthermore, no additional high-temperature is necessary since laser or a flash lamp can be used to improve battery performance. After the battery device is fabricated on the silicon substrate, the silicon substrate is removed. In order to prevent deformation of the battery that may occur as the silicon substrate is removed, an additional silicon oxide substrate is provided between the battery and the silicon substrate. Also, another silicon layer is used to effectively prevent device deformation, pollution, etc. that may occur during transfer and to enhance the accuracy of transfer. Accordingly, the battery device can be effectively fabricated and transferred onto the plastic substrate without device deformation.

While the present disclosure has been described with respect to the specific embodiments, it will be apparent to those skilled in the art that various changes and modifications may be made without departing from the spirit and scope of the disclosure as defined in the following claims.

What is claimed is:

1. A method for fabricating a flexible electronic device, comprising:
forming a separation layer on a front surface of a sacrificial substrate;
fabricating an electronic device on the separation layer;
removing the separation layer by irradiating laser to a back surface of the sacrificial substrate; and
transferring the electronic device separated from the sacrificial substrate as the separation layer is removed to a flexible substrate.

2. The method for fabricating a flexible electronic device according to claim 1, wherein the sacrificial substrate is made of a material which is transparent to the laser irradiated to the back surface.

3. The method for fabricating a flexible electronic device according to claim 2, wherein the separation layer is an amorphous silicon layer.

4. The method for fabricating a flexible electronic device according to claim 3, wherein the amorphous silicon layer outgases hydrogen when the laser is irradiated.

5. The method for fabricating a flexible electronic device according to claim 1, wherein the support layer comprises polydimethylsiloxane.

6. A method for fabricating a flexible secondary battery, comprising:
forming an amorphous silicon layer on a front surface of a glass substrate;
forming a battery layer of a secondary battery by sequentially laminating a current collector, a cathode, an electrolyte layer, an anode and a packaging material on the amorphous silicon layer;
bonding a support layer with the battery layer;
outgassing hydrogen from the amorphous silicon layer by irradiating laser to a back surface of the glass substrate; and
after the glass substrate is separated by the hydrogen outgassing, bonding another support layer with the other side of the battery layer with the support layer bonded.

7. A method for fabricating a flexible secondary battery, comprising:
forming an amorphous silicon layer on a front surface of a glass substrate;
forming a battery layer of a secondary battery by sequentially laminating a current collector, a cathode, an electrolyte layer, an anode and a packaging material on the amorphous silicon layer;
bonding a support layer with the battery layer;
outgassing hydrogen from the amorphous silicon layer by irradiating laser to a back surface of the glass substrate; and
after the glass substrate is separated by the hydrogen outgassing, coating a material the same as that of the support layer on the other side of the battery layer with the support layer bonded, such that the battery layer is inserted into the support layer.

8. A method for fabricating a plastic battery device, comprising:
preparing a battery layer on a sacrificial substrate;
removing the sacrificial substrate; and
transferring the battery layer to a plastic substrate using a transfer layer.

9. The method for fabricating a plastic battery device according to claim 8, which further comprises, before said removing the sacrificial substrate, bonding a supporting substrate with the battery layer.

10. The method for fabricating a plastic battery device according to claim 9, wherein the sacrificial substrate and the supporting substrate are respectively a first silicon substrate and a second silicon substrate.

11. A method for fabricating a plastic secondary battery, comprising:
forming a silicon oxide layer on a plastic substrate;
forming a cathode on the silicon oxide layer;
crystallizing the cathode by irradiating a laser beam to the cathode;
sequentially forming an electrolyte layer and an anode on the cathode; and
forming a packaging material layer on the anode.

12. The method for fabricating a plastic secondary battery according to claim 11, wherein the silicon oxide layer has a thickness of 100-500 nm.
